(19) United States
(12) Patent Application Publication
(10) Pub. No.: US 2022/0276306 A1
(43) Pub. Date: Sep. 1, 2022

(54) COMMUNICATION METHOD AND ITS SYSTEM BETWEEN INTERCONNECTED DIE AND DSP/FPGA

(71) Applicant: 58th Research Institute of China Electronics Technology Group Corporation, Wuxi, Jiangsu (CN)

(72) Inventors: Jinghe Wei, Wuxi, Jiangsu (CN); Letian Huang, Wuxi, Jiangsu (CN); Zongguang Yu, Wuxi, Jiangsu (CN); Wenxu Cao, Wuxi, Jiangsu (CN); Taojie Ding, Wuxi, Jiangsu (CN); Guozhu Liu, Wuxi, Jiangsu (CN)

(21) Appl. No.: 17/626,823

(22) PCT Filed: Dec. 16, 2021
(86) PCT No.: PCT/CN2021/138699

§ 371 Date: Jan. 13, 2022

(30) Foreign Application Priority Data
Feb. 5, 2021 (CN) 202110160531.7

(51) Int. Cl. G01R 31/3185; G01R 31/317

(52) U.S. Cl. CPC G01R 31/318533; G01R 31/31705; G01R 31/31713

(57) ABSTRACT

The invention relates to a communication method and its system between interconnected die and DSP/FPGA. The method includes multiple data interfaces. Each data interface is provided with a different protocol conversion module, wherein the data interface communication includes data input conversion and data output conversion; wherein during input conversion, the external data is converted into a unified data protocol format by protocol conversion module, which is transmitted to the network on die for unified data transmission; wherein during output conversion, the internal data is converted into different data protocol formats by protocol conversion module, and then enters different data interfaces and is transmitted to the DSP/FPGA. This method allows each device and component to be connected to the multi-die system in any form, which improves the flexibility of the system.

### BACKGROUND OF THE INVENTION

### 1. Field of the Invention

The invention relates to a communication system between interconnected die and DSP/FPGA, in particular to a communication method and its system between interconnected die and DSP/FPGA.

### 2. Description of the Related Art

With the development of digital integrated circuits, SoC (system on chip, which refers to the integration of multiple functional modules on one silicon chip) has almost become a necessary solution for realizing high-performance systems. Manufacturers continue to expand SoC scale to meet user needs for product performance. However, limited by factors such as processing technology, Moore's Law (that is, the rule that the number of transistors that can be accommodated on an integrated circuit doubles every 24 months) is gradually failing, which makes its costs and development cycles to expand the scale of integrated circuits on a single silicon chip become extremely high.

In the future, integrated circuits will develop towards multi-die integration, that is, multiple chip components that have different functions and have been verified and are not packaged are interconnected and assembled, and packaged as a whole chip in the same package to form a NoP (Network on Package). These dies can use different processes and come from different manufacturers, thus greatly shortening and reducing the development cycle and difficulty.

With the advent of big data and the development of artificial intelligence and other technologies, people's requirements for computing power continue to increase. In the future, multi-die systems will be inseparable from devices with powerful parallel computing power such as FPGA (Field Programmable Gate Array), DSP (Digital Signal Processor) and other dedicated accelerators. Their external interface types are rich and different from each other. When the dies of these devices are assembled into a whole, the current multi-die system generally uses a dedicated and fixed protocol interface to directly connect them. The fixed protocol interfaces correspond to fixed hardware circuits. This means that these devices will assume fixed roles and perform fixed functions in the system, which will reduce the flexibility of the system and increase the time cost of system reconstruction.

### SUMMARY OF THE INVENTION

In order to solve the above problem, the invention provides a communication method between interconnected die and DSP/FPGA. This method can overcome the shortcomings of poor flexibility and poor reconfigurability of the above-mentioned traditional methods, and realizes the flexible assembly, rapid definition and rapid realization of multi-die systems including DSP/FPGA with the help of scalable high-speed interconnected dies to set multiple data interfaces.

The specific technical solutions are:

A communication method between interconnected die and DSP/FPGA includes multiple data interfaces and each of the data interfaces is provided with a different protocol conversion module. The data interface communication includes data input conversion and data output conversion. During the data input conversion, the external data of the DSP/FPGA is converted into a unified data protocol format by the protocol conversion module, which is transmitted to the network on die inside the interconnected die for unified data transmission; During the data output conversion, the internal data of the interconnected die is converted into different data protocol formats by the protocol conversion module, and then enters different data interfaces and is transmitted to the DSP/FPGA.

A communication system between interconnected die and DSP/FPGA, wherein the interconnected die is provided with multiple data interfaces, and the multiple data interfaces are used to connect with the DSP/FPGA. Each of the data interfaces is provided with a different protocol conversion circuit. The protocol conversion circuit is used to convert different external data into a unified data protocol format to enter the interconnected die and convert the data inside the interconnected die into a corresponding data protocol format according to the destination data interface.

Preferably, the data interface includes the master device interface, the slave device interface and the peer device interface.

Further, the master device interface includes: an interrupt interface, a DDR data interface, an SPI interface and a JTAG interface. The interrupt interface is used to receive interrupt requests from the interconnected die. The DDR data interface is used for the DSP/FPGA to transmit data in the master device mode. The SPI interface is used to load the BOOT ROM startup code when the master device starts. The JTAG interface is used to debug the master device.

Further, the slave device interface includes: a PCIe interface and an interrupt interface. The PCIe interface is used to transmit data. The interrupt interface is used to send out the interrupt request from the slave device.

Further, the peer device interface includes the RapidIO interface, which is used to transmit data.

Compared with the prior art, the invention has the following beneficial effects:

The communication method for interconnected dies and DSP/FPGA provided by the invention converts external data into a unified data protocol format for internal transmission and converts internal data into a corresponding data protocol format and transmits it to DSP/FPGA, so that each device and component can be connected to a multi-die system in any form, which improves the flexibility of the system.

### BRIEF DESCRIPTION OF THE DRAWINGS

FIG. 1 is a schematic diagram of the communication method between interconnected die and DSP/FPGA.

FIG. 2 is a schematic structural diagram of the communication system between interconnected die and DSP/FPGA.

### DETAILED DESCRIPTION OF THE PREFERRED EMBODIMENTS

The invention will now be further explained according to the attached figures.

### Embodiment 1

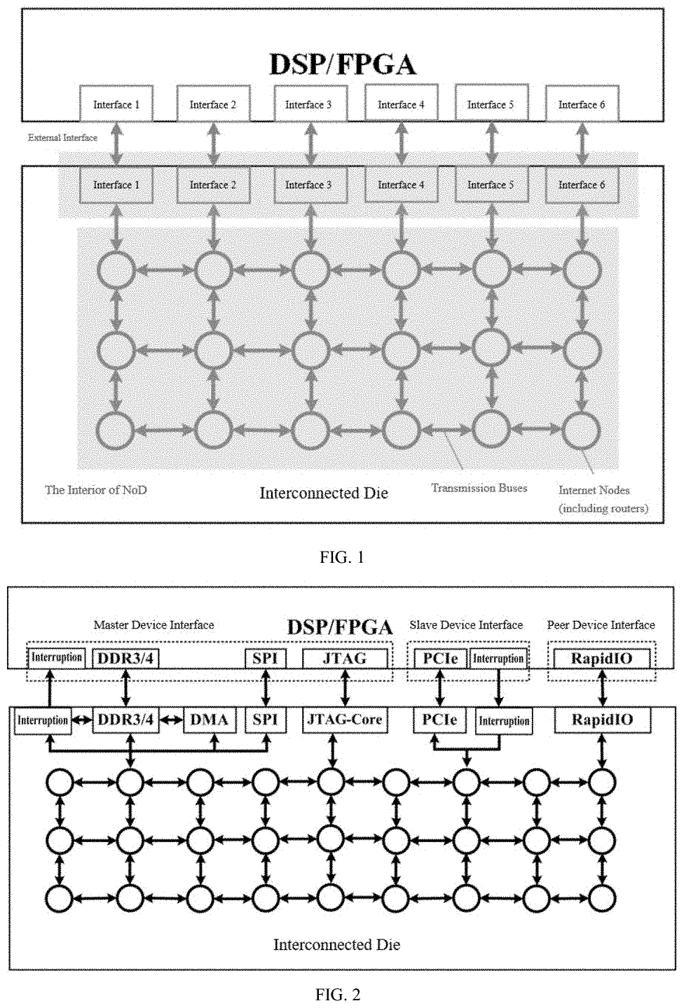

As shown in FIG. 1 and FIG. 2, a communication method between interconnected die and DSP/FPGA includes multiple data interfaces and each of the data interfaces is provided with a different protocol conversion module. The data interface communication includes data input conversion and data output conversion. During the data input conversion, the external data of the DSP/FPGA is converted into a unified data protocol format by the protocol conversion module, which is transmitted to the network on die inside the interconnected die for unified data transmission; During the data output conversion, the internal data of the interconnected die is converted into different data protocol formats by the protocol conversion module, and then enters different data interfaces and is transmitted to the DSP/FPGA.

As shown in FIG. 1, the interior of the interconnected die is a NoD (Network on Die), which is composed of data nodes, routers, and transmission buses. The protocol conversion modules are respectively connected to the boundary nodes of the NoD. The protocol conversion module is used to transmit data packets from the interface or other interconnected dies, and the interconnected dies realize data transmission by means of packet switching. NoD adopts a unified data protocol format. The protocol obtains multiple types of external data interfaces through a variety of protocol conversion circuits. Interfaces 1 to 6 in FIG. 1 all use different data protocol formats as data interfaces for connecting with other dies. At the same time, the DSP/FPGA is also provided with a variety of corresponding data interfaces. Connect the DSP/FPGA with the interconnected die according to the method shown in FIG. 1 and it can be realized that an efficient communication between the DSP/FPGA and the interconnected die.

This communication method is based on the rich external interface types of the extensible high-speed interconnection die, and connects the DSP/FPGA to the interconnection die, so that each device and component can be connected to a multi-die system in any form, which improves the flexibility of the system.

### Embodiment 2

As shown in FIG. 1 and FIG. 2, a communication system between interconnected die and DSP/FPGA, wherein the interconnected die is provided with multiple data interfaces, and the multiple data interfaces are used to connect with the DSP/FPGA. Each of the data interfaces is provided with a different protocol conversion circuit. The protocol conversion circuit is used to convert different external data into a unified data protocol format to enter the interconnected die and convert the data inside the interconnected die into a corresponding data protocol format according to the destination data interface.

The data interface includes the master device interface, the slave device interface and the peer device interface.

The master device interface includes: an interrupt interface, a DDR data interface, an SPI interface and a JTAG interface. The interrupt interface is used to receive interrupt requests from the interconnected die. The DDR data interface is used for the DSP/FPGA to transmit data in the master device mode. The SPI interface is used to load the BOOT ROM startup code when the master device starts. The JTAG interface is used to debug the master device.

The slave device interface includes: a PCIe interface and an interrupt interface. The PCIe interface is used to transmit data. The interrupt interface is used to send out the interrupt request from the slave device.

The peer device interface includes the RapidIO interface, which is used to transmit data.

The reason why the invention can realize the multi-type interface communication between the extensible high-speed interconnected bare core and DSP/FPGA benefits from two advantages of interconnected dies: First, the interior of the interconnected die adopts the NoD of a unified protocol, so it can support and be compatible with various types of interfaces; second, the interconnected die is equipped with a wealth of external interface types, so it can match various interface types of various DSP and FPGA, and support DSP and FPGA to access the system in different forms.

The communication between different devices generally adopts the master-slave mode, that is, the master device sends out data control information (read command or write command) and the slave device responds. Then the data transmission is completed. (Interruption and debugging are exceptions; during interruption, the master device does not send control information, but receive the interrupt request from the slave device; during debugging, other devices read the register data of the master device through the debugging interface of the master device). Therefore, each device generally has three possible forms in the system: master device, slave device, or peer device. The peer device can be used as both a master device and a slave device during transmission. For the same data protocol, there are three types of interfaces, namely, the master device interface, the slave device interface, and the peer device interface, which are respectively connected to the above three types of devices. There is a wealth of interface types in the interconnect die, which not only supports multiple data protocols, but also supports device interfaces of different natures for the same data protocol. It provides great convenience for the interconnection of DSP/FPGA. Table 1 shows several common data protocols and interface properties in DSP/FPGA.

TABLE 1
Common data protocols and interface properties in DSP/FPGA

| Data Protocol Format | Interface Property |
|---|---|
| DDR3/4 | Master device interface/ |
| | Slave device interface |
| SPI | Master device interface |
| JTAG | Slave device interface |
| PCIe | Slave device interface |
| RapidIO | Peer device interface |
| Interruption | Slave device interface |

DDR3/4 is the third or fourth generation of DDR.

As shown in FIG. 2, a communication system between interconnected die and DSP/FPGA, wherein interconnected die and DSP/FPGA are all provided with the master device interface, the slave device interface and the peer device interface. the master device interface includes: an interrupt interface, a DDR data interface, an SPI interface and a JTAG interface. The interrupt interface is used to receive interrupt requests from the interconnected die. The DDR data interface is used for the DSP/FPGA to transmit data in the master device mode. The SPI interface is used to load the BOOT ROM startup code when the master device starts. The JTAG interface is used to debug the master device. The slave device interface includes: a PCIe interface and an interrupt interface. The PCIe interface is used to transmit data. The interrupt interface is used to send out the interrupt request from the slave device. The peer device interface includes the RapidIO interface, which is used to transmit data.

In the communication process between DSP/FPGA and interconnected die, all data from DSP/FPGA will eventually be converted into a unified data protocol format into the NoD of the interconnected die through different types of data interfaces. At the same time, data from NoD will also be converted into different data protocol formats according to its own destination address, and then enter different types of data interfaces, and be finally transmitted to DSP/FPGA.

Connect functional dies such as DSP and FPGA to an interconnected die through interconnected die. The interconnected dies are used to realize interface conversion and data communication. During system construction, each die can be made into multiple devices and arbitrary forms, so as to play different roles and perform different functions, which facilitates the flexible assembly, rapid definition and rapid implementation of the system. It also greatly improves the flexibility of system assembly and reduces the time cost of system reconfiguration.

The technical principle of the invention has been described above in conjunction with specific embodiments. These descriptions are only for explaining the principle of the invention, and cannot be construed as limiting the protection scope of the invention in any way. Based on the explanation here, those skilled in the art can think of other specific implementation methods of the invention without creative work, and these methods will fall within the protection scope of the claims of the invention.

1. A communication method between interconnected die and DSP/FPGA, wherein it includes multiple data interfaces and each of the data interfaces is provided with a different protocol conversion module; wherein the data interface communication includes data input conversion and data output conversion;
wherein during the data input conversion, the external data of the DSP/FPGA is converted into a unified data protocol format by the protocol conversion module, which is transmitted to the network on die inside the interconnected die for unified data transmission;
wherein during the data output conversion, the internal data of the interconnected die is converted into different data protocol formats by the protocol conversion module, and then enters different data interfaces and is transmitted to the DSP/FPGA;

2. A communication system between interconnected die and DSP/FPGA, wherein the interconnected die is provided with multiple data interfaces, and the multiple data interfaces are used to connect with the DSP/FPGA; wherein each of the data interfaces is provided with a different protocol conversion circuit; wherein the protocol conversion circuit is used to convert different external data into a unified data protocol format to enter the interconnected die and convert the data inside the interconnected die into a corresponding data protocol format according to the destination data interface;

3. The communication system between interconnected die and DSP/FPGA of claim 2, wherein the data interface includes the master device interface, the slave device interface and the peer device interface;

4. The communication system between interconnected die and DSP/FPGA of claim 3, wherein the master device interface includes: an interrupt interface, a DDR data interface, an SPI interface and a JTAG interface; wherein the interrupt interface is used to receive interrupt requests from the interconnected die; wherein the DDR data interface is used for the DSP/FPGA to transmit data in the master device mode; wherein the SPI interface is used to load the BOOT ROM startup code when the master device starts; wherein the JTAG interface is used to debug the master device;

5. The communication system between interconnected die and DSP/FPGA of claim 3, wherein the slave device interface includes: a PCIe interface and an interrupt interface; wherein the PCIe interface is used to transmit data; wherein the interrupt interface is used to send out the interrupt request from the slave device;

6. The communication system between interconnected die and DSP/FPGA of claim 3, wherein the peer device interface includes the RapidIO interface, which is used to transmit data.
